(19) United States
(12) Patent Application Publication
(10) Pub. No.: US 2016/0029514 A1
(43) Pub. Date: Jan. 28, 2016

(54) A LIQUID COOLED DEVICE ENCLOSURE

(71) Applicant: ASELSAN ELEKTRONIK SANAYI VE TICARET ANONIM SIRKETI, ANKARA (TR)

(72) Inventors: Ugur ALAKOC, Ankara (TR); Muharrem KAYNAKOZ, Ankara (TR); Tolga AYYILMAZ, Ankara (TR)

(73) Assignee: Aselsan Elektronik Sanayi ve Ticaret Anonim Sirketi, Ankara (TR)

(21) Appl. No.: 14/434,406

(22) PCT Filed: Apr. 8, 2014
(86) PCT No.: PCT/TR2014/000135

§ 371 Date: Apr. 9, 2015

(30) Foreign Application Priority Data
Dec. 31, 2013 (TR) 2013/15630

(51) Int. Cl. H05K 7/20

(52) U.S. Cl. CPC H05K 7/20254

(57) ABSTRACT

The present invention essentially relates to a liquid cooled device enclosure (1) which is designed for cooling electronic modules having high heat dissipation by using micro channel liquid cooling method.

### FIELD OF THE INVENTION

The present invention relates to cooling electronic modules having high heat dissipation by using micro channel liquid cooling method.

### BACKGROUND OF THE INVENTION

Today, cold plates are used for cooling the device enclosures wherein the electronic modules are located together. The modules are mounted on the cold plates and the heat released from the modules is transferred to the cold plate via conduction. The liquid flowing through the channels of the cold plate convect the heat dissipated from the modules and transfer the heat to the cooling unit. The liquid channels are produced such that they will be constructed of many channels next to each other in mini or micro scale in order to increase the heat transfer in cooling channels.

In liquid cooling applications in which ethylene glycol and water mixture is used, liquid leakage causes short circuit in the electronic boards and thus causes the device to break down. In current applications, the probability of the electronic units malfunctioning increases in case of liquid leakage since the electronic modules are mounted on the cold plate.

After the coolant enters into the electronic unit, it is distributed to every cold plate inside the unit via a liquid distribution manifold. While flowing inside the cold plate, the coolant receives the heat released in electronic modules and then exits the unit by being collected in the accumulation manifold to which the cold plates are connected. The cooling structures used in this cooling method complicate design and production of the device, and cause use of liquid couplings twice as much as the number of the cold plates in the unit. This case also brings maintenance and repair necessity for cooling components as well as electronic members in the unit, decreases the reliability and the lifetime of the unit.

U.S. Pat. No. 5,808,866 (A), an application known in the state of the art, discloses a container which is suitable for harsh environments, which is light-weighted due to its production, and has a card cage, carrying handle, a vibration isolator assembly, cooling system, and power supply.

International Patent document no WO0213588 (A1), an application known in the state of the art, discloses a cooling apparatus which is designed to be used in wireless telecommunication bases stations. The cooling apparatus has a closed circuit liquid cooling system; it can receive the liquid coming from the electronic components by means of the low profile extrusions having micro channel system and transfer to the cooling system.

### SUMMARY OF THE INVENTION

The objective of the present invention is, to develop a liquid cooled device enclosure wherein the electronic modules are not in contact with the liquid channels and thus the possibility of malfunctioning of the electronic modules is avoided in case of liquid leakage.

A further objective of the present invention is to provide a liquid cooled device enclosure wherein the liquid couplings and the manifold structures that are used for liquid distribution and collection lines are not needed for liquid connections inside the device enclosure.

Another objective of the present invention is to provide a liquid cooled device enclosure wherein the cooling structure is comprised of minimum number of mechanical components.

Yet another objective of the present invention is to provide a liquid cooled device enclosure which is sealed and thus which preserves the electronic modules against the harmful environmental conditions.

### BRIEF DESCRIPTION OF THE DRAWINGS

FIG. 1 is the perspective view of the liquid cooled device enclosure.

FIG. 2 is the perspective view of the liquid cooled device enclosure wherein its inside is observed.

FIG. 3 is the perspective view of the liquid cooled device enclosure wherein its inside is observed from another angle.

FIG. 4 is the below perspective view of the liquid cooled device enclosure wherein its inside is observed.

### DETAILED DESCRIPTION OF THE INVENTION

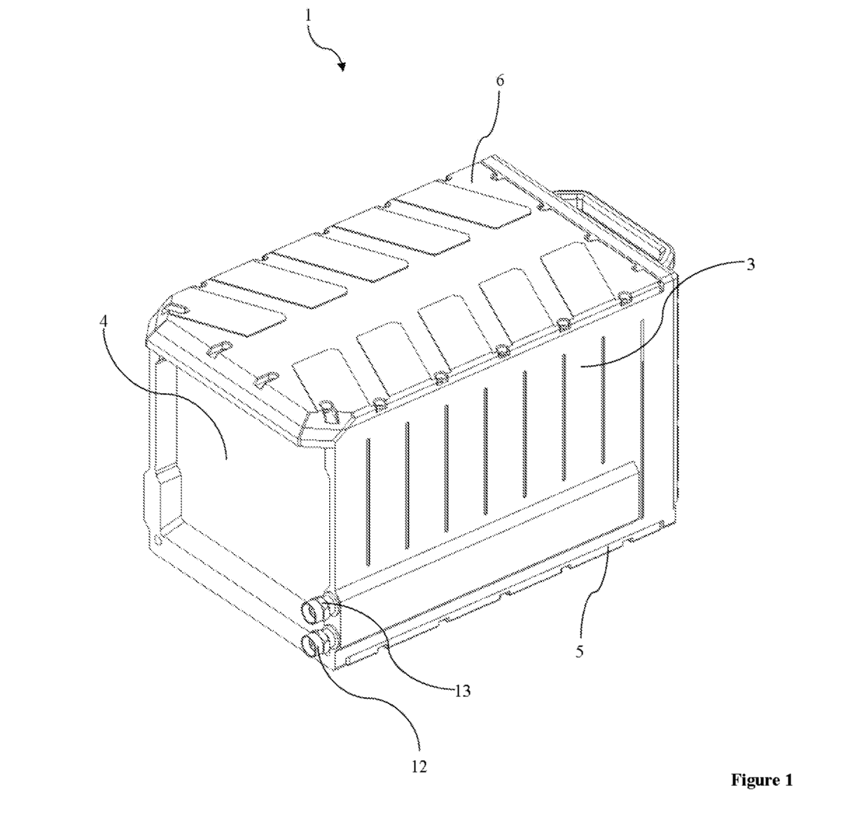

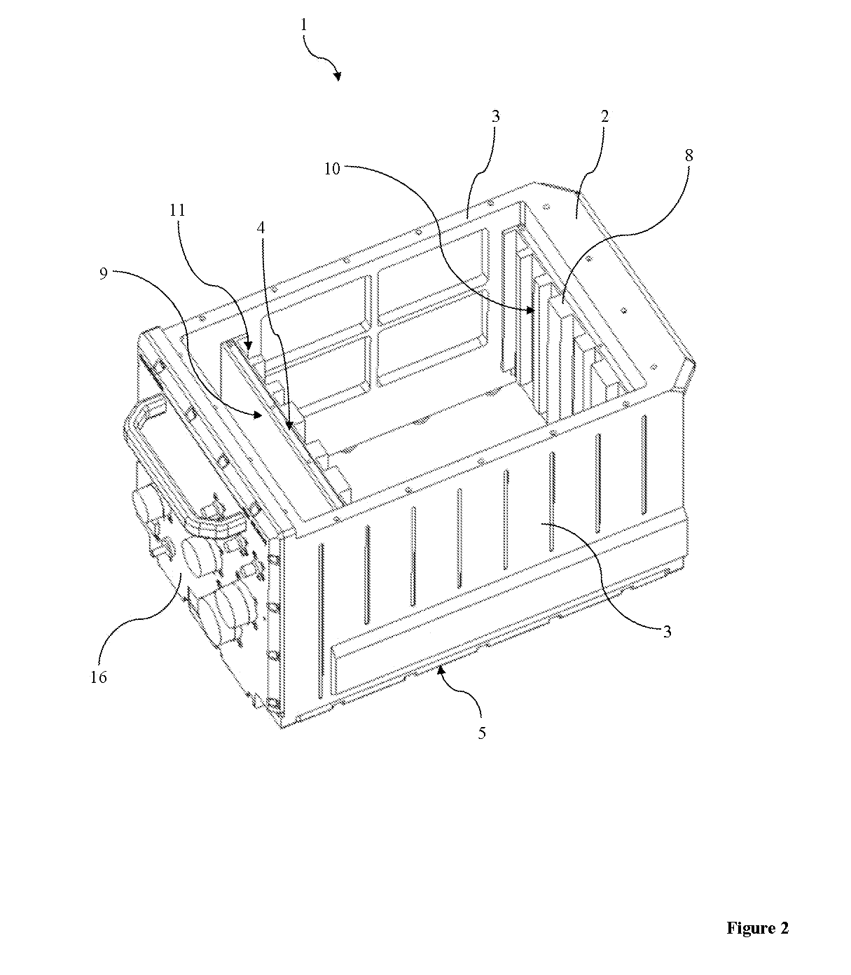

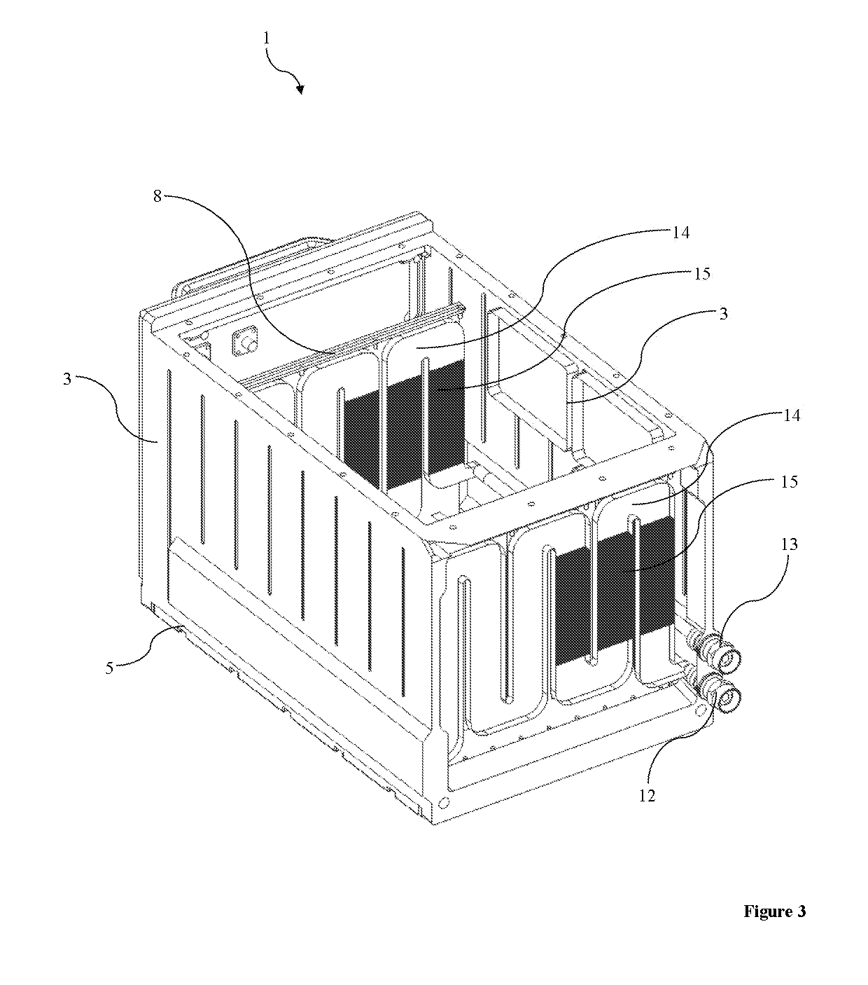

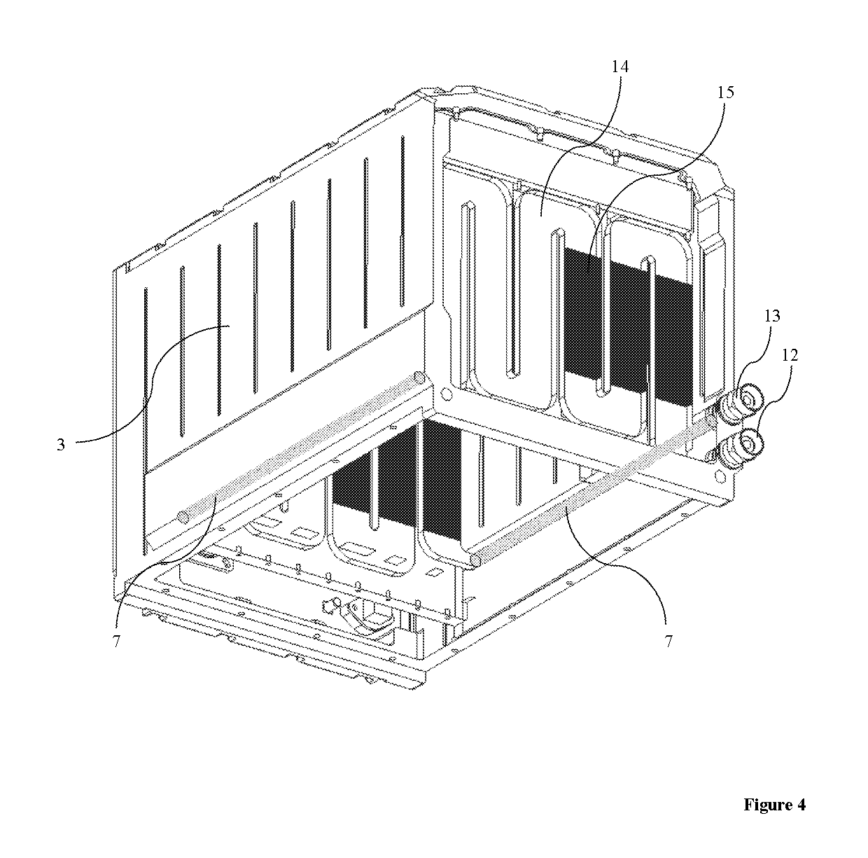

“A liquid cooled device enclosure” developed to fulfill the objectives of the present invention is illustrated in the accompanying figures, in which:
FIG. 1 is the perspective view of the liquid cooled device enclosure.
FIG. 2 is the perspective view of the liquid cooled device enclosure wherein its inside is observed.
FIG. 3 is the perspective view of the liquid cooled device enclosure wherein its inside is observed from another angle.
FIG. 4 is the below perspective view of the liquid cooled device enclosure wherein its inside is observed.

The components given in the figures are assigned reference numerals as follows:
17. Liquid cooled device enclosure
18. Device chassis
19. Device chassis sidewall
20. Device chassis slotted wall
21. Lower lid
22. Upper lid
23. Plain liquid channel
24. Electronic module compartment
25. Electronic module compartment sidewall
26. Electronic module compartment slotted wall
27. Slot
28. Inlet liquid quick coupling
29. Outlet liquid quick coupling
30. Liquid channel
31. Micro channel
32. Device front panel

The inventive liquid cooled device enclosure (1) which is used for cooling electronic components having high heat dissipation comprises
at least one device enclosure (2),
device chassis sidewall (3) located vertical to the ground correspondingly,
device chassis slotted wall (4) which is vertical to the ground and forms the device chassis (2) by connecting with the device chassis sidewalls (3),
at least one lower lid (5) which is located parallel to the ground facing the bottom of the device chassis (2),
at least one upper lid (6) which is parallel to the lower lid (5), vertical to the device chassis sidewalls (3) and device chassis slotted walls (4), and covers the device chassis (2), plain liquid channel (7) which is located on the device chassis sidewalls (3), at least one electronic module compartment (8) which is located on the inner surfaces of the device chassis slotted walls (4),
electronic module compartment sidewall (9) which is the surface of the electronic module compartment (8) facing the device chassis front panel (16),
electronic module compartment slotted wall (10) which is the inner surface of the electronic module compartments (8) facing each other,
at least one slot (11) which is present on the electronic module compartment slotted walls (10) correspondingly and in which the electronic modules are mounted,
at least one inlet liquid quick coupling (12) which is present on the outer surface of the device chassis (2) and through which the liquid enters into the device chassis (2),
at least one outlet liquid quick coupling (13) which is present on the outer surface of the device chassis (2) and through which the liquid exits out of the device chassis (2),
liquid channel (14) which corresponds to the slots (11) and present on the electronic module compartment slotted wall (10),
at least one micro channel (15) which is present inside the liquid channels (14) corresponding to the slots (11),
at least one device front panel (1) which provides the interface for the device connectors and which protects the front surface of the device chassis (2) by covering.

In the inventive liquid cooled device enclosure (1), plain liquid channels (7) are present on the device chassis sidewalls (3). The liquid enters into the device chassis (2) through the inlet liquid quick coupling (12) present on the outer surface of the device chassis (2), and moves along the electronic module compartment slotted wall (10) in the liquid channels (14) with serpentine flow pattern. Then, the liquid passes to the electronic module compartment slotted wall (10) through the plain liquid channel (7) which is preferably circular along the device chassis sidewall (3). After the liquid flows through the liquid channels (14) with serpentine flow pattern through the electronic module compartment slotted walls (10), it passes through the plain liquid channel (7) on the device chassis sidewall (3), and flows through the outlet liquid quick coupling (13) on the device chassis (3), and exits out of the liquid cooled device enclosure (1).

The electronic modules are attached to the device chassis slotted walls (4) located correspondingly on the device chassis (2). The heat generated by the electronic modules is transferred to the slots (11) on the edges of the device chassis (2) via conduction. The liquid cools the device chassis (2) by flowing through the plain liquid channels (7) on the device chassis sidewalls (3) and the liquid channels (14) on the electronic module compartment slotted walls (10). There are micro channels (15) in the liquid channels (14) corresponding to electronic module compartment slotted walls (10) on which the electronic modules with high heat dissipation are attached. The micro channels (15) increase the heat transfer area and forced convection in the liquid channel (14), and enable the heat generated by electronic modules to be transferred to the liquid more effectively. There are lower lid (5) and upper lid (6) which prevent the contact of the electronic modules with the environment and provide sealing, under and above the device chassis (2).

The production method of the device chassis (2) enabling three dimensional flow is vacuum brazing. The liquid cooled device enclosure (1) is designed suitable for single direction vacuum brazing technique mechanically. The mechanical parts forming the device chassis (2) are bonded to the micro channels (micro fins) (15) in the liquid channels (14) by brazing in single stage. The production of the device chassis (2) is completed when the details are made on the device chassis (2) with machining after brazing.

In one alternative embodiment of the invention, mini channels can be used instead of micro channels (15).

By means of the inventive liquid cooled device enclosure (1), the coolant flows through the plain liquid channels (7) inside the device chassis sidewalls (3) and the liquid channels (14) on the electronic module compartment slotted walls (10), and thus the electronic modules are avoided from malfunctioning in case of liquid leakage since there is no contact with the electronic modules and the cooling surface through which the liquid flows.

In one embodiment of the invention, in device chassis (2), deionized water flows through the plain liquid channel (7) and the liquid channel (14) present inside the electronic module compartment slotted wall (10) in single phase.

In the alternative embodiment of the invention, in device chassis (2), coolant obtained by mixing deionized water and ethylene glycol in different amounts flows through the plain liquid channel (7) and the liquid channel (14) present inside the electronic module compartment slotted wall (10) in single phase.

In the alternative embodiment of the invention, in device chassis (2), coolant obtained by mixing deionized water, anti-corrosive liquid and ethylene glycol in different amounts flows through the plain liquid channel (7) and the liquid channel (14) present inside the electronic module compartment slotted wall (10) in single phase.

In the alternative embodiment of the invention, in device chassis (2), per fluorocarbon coolants which are electrically non-conducting flow through the plain liquid channel (7) and the liquid channel (14) present inside the electronic module compartment slotted wall (10) in two phase (liquid and gas).

In the alternative embodiment of the invention, in device chassis (2), chlorofluorocarbon coolants flow through the plain liquid channel (7) and the liquid channel (14) present inside the electronic module compartment slotted wall (10) in two phase.

In the alternative embodiment of the invention, in device chassis (2), hydro fluorocarbon coolants flow through the plain liquid channel (7) and the liquid channel (14) present inside the electronic module compartment slotted wall (10) in two phase.

Making the connection of inlet liquid quick coupling (12) and outlet liquid quick coupling (13) on the device chassis (2) is sufficient in order that the coolant can flow inside the device chassis (2) plain liquid channel (7) and the liquid channel (14) present on the electronic module compartment slotted wall (10). With this invention, there is no need for liquid connections, manifold structures used for liquid distributing and collecting lines inside the device enclosure (1). Cooling structure is comprised of less mechanic parts relative to the current liquid cooling embodiments. Electronic modules remain in a closed and sealed enclosure and are protected from corrosion effects of the environmental conditions.

1. A liquid cooled device enclosure, which is used for cooling electronic components having high heat dissipation, comprising:
at least one device enclosure,
a plurality of device chassis sidewalls located vertical to the ground correspondingly,
a plurality of device chassis slotted walls which is vertical to the ground and forms a device chassis by connecting with the device chassis sidewalls,
at least one lower lid which is located parallel to the ground on the part of the device chassis facing the ground,
at least one upper lid which is parallel to the lower lid, vertical to the device chassis sidewalls and the device chassis slotted walls, and covers the device chassis,
a plain liquid channel which is located on the device chassis sidewalls, at least one electronic module compartment which is located on the inner surfaces of the device chassis slotted walls,
an electronic module compartment sidewall which is the surface of the electronic module compartment facing a device chassis front panel,
a plurality of electronic module compartment slotted walls which is the inner surface of the electronic module compartments facing each other,
at least one slot which is present on the electronic module compartment slotted walls correspondingly and in which a plurality of electronic modules are located,
at least one inlet liquid quick coupling which is present on the outer surface of the device chassis and through which liquid enters into the device chassis,
at least one outlet liquid quick coupling which is present on the outer surface of the device chassis and through which liquid exits out of the device chassis,
a plurality of liquid channels which corresponds to the slot and are present on the electronic module compartment slotted walls,
at least one micro channel which is present on the liquid channels corresponding to the slot,
at least one device front panel which provides an interface for a device connectors and protects the front surface of the device chassis by covering.

2. The liquid cooled device enclosure of claim 1, wherein the micro channel is present in the liquid channels corresponding to the slot.

3. The liquid cooled device enclosure of claim 1, wherein liquid enters into the device chassis through the inlet liquid quick coupling which is present on the outer surface of the device chassis; wherein liquid flows through the electronic module compartment slotted walls with serpentine flow pattern.

4. The liquid cooled device enclosure of claim 1, wherein liquid passes to the electronic module compartment slotted walls through the plain liquid channel which is preferably circular along the device chassis sidewall.

5. The liquid cooled device enclosure of claim 4, wherein liquid passes through the plain liquid channel on the devices chassis sidewalls after liquid flows through the liquid channels with serpentine flow pattern through the electronic module compartment slotted walls.

6. The liquid cooled device enclosure of claim 1, wherein the device chassis slotted walls are located correspondingly on the device chassis and the electronic modules are attached to the device chassis slotted walls.

7. The liquid cooled device enclosure of claim 1, wherein the slot is located on the edges of the device chassis; wherein heat generated by the electronic module is transferred via a conduction.

8. The liquid cooled device enclosure of claim 1, wherein the device chassis cooled by the fluid flowing through the plain liquid channels on the device chassis sidewalls and the liquid channels on the electronic module compartment slotted walls.

9. The liquid cooled device enclosure of claim 1, wherein the micro channel is located on the liquid channels corresponding to the electronic module compartment slotted walls; wherein the electronic modules with high heat dissipation are attached to the electronic module compartment slotted walls.

10. The liquid cooled device enclosure of claim 9, wherein the micro channels is present in the liquid channels and enables the transfer of heat generated by the electronic modules to flow more effectively by increasing the heat transfer area and forced convection in the liquid channels.

11. The liquid cooled device enclosure of claim 1, wherein the lower lid and the upper lid present under and above the device chassis; wherein the lower lid and the upper lid prevent the contact of the electronic modules with the environment and provide sealing.

12. The liquid cooled device enclosure of claim 1, wherein the device chassis enables three dimensional to flow inside the liquid channels; wherein the device chassis is manufactured by brazing and post-machining after brazing.

13. The liquid cooled device enclosure of claim 1, wherein the device chassis, the plain liquid channel and the liquid channels are presented on the electronic module compartment slotted walls; wherein liquid flows are designed to avoid the electronic modules malfunctioning in case of a liquid leakage since the electronic modules are not in contact with the cooling surface under which liquid passes.

14. The liquid cooled device enclosure of claim 1, wherein the device chassis, the plain liquid channel and the liquid channels are presented on the electronic module compartment slotted walls in which a deionized water flows in a single phase.

15. The liquid cooled device enclosure of claim 1, wherein the device chassis, the plain liquid channel and the liquid channels are presented on the electronic module compartment slotted walls in which a coolant is obtained by mixing ethylene glycol and deionized water in different amounts and the coolant flows in single phase.

16. The liquid cooled device enclosure of claim 1, wherein the device chassis, the plain liquid channel and the liquid channels are presented on the electronic module compartment slotted walls in which the coolant is obtained by mixing ethylene glycol, deionized water and anti-corrosive liquid in different amounts and the coolant flows in single phase.

17. The liquid cooled device enclosure of claim 1, wherein the device chassis, the plain liquid channel and the liquid channels are presented on the electronic module compartment slotted walls in which electrically non-conductive per fluorocarbon fluids flow in two phases (liquid and gas).

18. The liquid cooled device enclosure of claim 1, wherein the device chassis, the plain liquid channel and the liquid channels are presented on the electronic module compartment slotted walls in which chlorofluorocarbon fluids flow in two phase.

19. The liquid cooled device enclosure of claim 1, wherein the device chassis, the plain liquid channel and the liquid channels are presented on the electronic module compartment slotted walls in which hydro fluorocarbon fluids flow in two phase.
